(19) United States
(12) Patent Application Publication
(10) Pub. No.: US 2021/0384712 A1
(43) Pub. Date: Dec. 9, 2021

(54) PANEL BOARD INCLUDING PANEL FOR AUTOMATICALLY ADJUSTING MOISTURE IN THE INTERIOR OF PANEL BOARD

(71) Applicant: NAEWOIKOREA Co., LTD., Seongnam-Si Gyeonggi-Do (KR)

(72) Inventor: Cheol Ho YANG, Seongnam-si (KR)

(73) Assignee: NAEWOIKOREA Co., LTD., Seongnam-Si Gyeonggi-Do (KR)

(21) Appl. No.: 17/228,338

(22) Filed: Apr. 12, 2021

(30) Foreign Application Priority Data
Jun. 5, 2020 (KR) 10-2020-0068234

(51) Int. Cl. H02B 1/30; C09D 5/00

(52) U.S. Cl. CPC H02B 1/306; B05D 1/02; C09D 5/00

(57) ABSTRACT

Disclosed is a panel board including a panel for automatically adjusting a humidity of an interior thereof, the panel board including an outer wall panel manufactured in a specific standard and a roof panel coupled to an upper side of the outer wall panel to define a roof thereof, and having a space part, in which various pieces of electric power equipment are installed, on the inner side thereof, wherein an interior and an exterior of a wall of the panel board are coated such that moisture absorption capacities of the interior and the exterior of the wall are different.

### CROSS-REFERENCE TO RELATED APPLICATIONS

A claim for priority under 35 U.S.C. § 119 is made to Korean Patent Application No. 10-2020-0068234 filed on Jun. 5, 2020 in the Korean Intellectual Property Office, the entire contents of which are hereby incorporated by reference.

### BACKGROUND

Embodiments of the inventive concept described herein relate to a panel board, and more particularly, relate to a panel board that is one panel member constituting a wall of the panel board, the panel board being capable of adjusting moisture in the interior of the panel board and preventing a dew condensation phenomenon by making the coating on an outer surface and an inner surface of the panel board different.

A panel board is equipment installed and used in an indoor or outdoor site, such as a building or a substation which requires a large use of electricity, and is an electric device for uniformly arranging and managing various switches, measuring instruments, and relays. A handling lever for opening and closing a circuit breaker of a high-voltage main circuit, and an break switch of a low-voltage main circuit, a voltmeter, an ammeter, a wattmeter, an integrating wattmeter, a current relay, and the like are installed in the panel board, and currents of a high voltage flow in the interior thereof.

Korean Utility Model No. 20-0280769 (Jun. 24, 2002) disclosed arrangement type panel boards connected to each other in a straight line and including a door, which may be opened and closed independently, on a front surface of the panel board. The arrangement type panel board has a simple box shape and the interior of the panel board is not air-tight, and thus the flows of air are not blocked in the interior of the panel board. Accordingly, the moisture in air is naturally introduced into the interior of the panel board, and the moisture becomes a main cause of weakening the insulation capacity of the panel board later.

In order to solve the problem, Korean Patent Application Publication No. 10-2011-0110876 provides a panel board including a low-power moisture collecting device capable of electrically removing moisture, the low-power moisture collecting device including a moisture collecting device body and a power control device to control temperature and moisture in the interior of the panel from the outside by separately providing a power unit and a moisture collecting unit such that the power unit and the moisture collecting unit are mounted on a panel door.

However, according to the conventional technology, because it is not easy to install and construct the panel board and the construction costs of the panel board are high and it is necessary to electrically remove moisture, it is necessary to consistently manage the panel board, for example, by checking various controllers and sensors that constitute the moisture collecting device of the conventional technology as well as to consistently supply electricity to the panel board to remove moisture in the interior of the panel board.

### SUMMARY

Embodiments of the inventive concept provide a panel board including a panel capable of automatically adjusting moisture in the interior of the panel board, the panel board capable of preventing insulation destruction of the panel board by moisture by reducing a difference between the temperatures of the exterior and the interior of the panel board to prevent a dew condensation phenomenon while adjusting moisture in the interior of the panel board, reducing the possibility of safety accidents, and improving the performance of the panel board.

In order to achieve the objectives, the inventive concept provides a panel board including an outer wall panel manufactured in a specific standard and a roof panel coupled to an upper side of the outer wall panel to define a roof thereof, and having a space part, in which various pieces of electric power equipment are installed, on the inner side thereof, wherein an interior and an exterior of a wall of the panel board are coated such that moisture absorption capacities of the interior and the exterior of the wall are different, whereby the moisture in the interior of the panel board may be automatically adjusted.

In a detailed description of the coating state of the panel board, water absorption coating of absorbing moisture is performed on an inner surface of the wall of the panel board, water repellency coating of suppressing absorption of moisture is performed on an outer surface of the wall of the panel board, moisture is absorbed to an interior of the panel board due to the water absorption coating of the inner surface, and moisture is prevented from permeating into the interior of the panel board due to the water repellency coating of the outer surface. The wall of the panel board is a single plate member, and the water absorption coating of the inner surface is finished through primary coating, and the water repellency coating of the outer surface is finished by performing secondary coating on an upper surface, on which the primary coating has been performed, after the primary coating.

The primary coating of the water absorption coating and the primary coating of the water repellency coating are performed such that a plurality of pores are generated after the coating, and the plurality of pores are generated due to porous composites.

According to an embodiment, the primary coating of the water absorption coating and the primary coating of the water repellency coating are performed such that a plurality of pores are generated after the coating, and the plurality of pores are generated due to bubbles generated during spray coating.

Further, a coating agent for the primary coating of the water absorption coating and the primary coating of the water repellency coating is manufactured by mixing a liquid base agent of 100 parts by weight and powder of 40 to 55 parts by weight.

Furthermore, the liquid base agent is obtained by mixing water of 100 parts by weight and a liquid mixture of 50 to 70 parts by weight.

Further, the liquid mixture is manufactured by mixing a polyurethane dispersion (PUD) resin of 100 parts by weight and an acryl resin of 40 to 55 parts by weight.

According to an embodiment, the powder is manufactured by mixing volcanic ash of 100 parts by weight, which is excellent in absorption of moisture and insulation of heat due to the porous structure thereof, and diatomite of 70 to 78 parts by weight, which is excellent in absorption of moisture, prevention of adsorption of contaminants, and performance of insulation of heat due to the porous structure thereof and dolomite of 55 to 65 parts by weight, which is excellent in a filling effect and performance of prevention of adsorption of contaminants.

Further, the powder may be manufactured by further mixing volcanic ash of 100 parts by weight and elvan of 30 to 35 parts by weight, which has moisture absorbing, fire retarding, and contaminant adsorption preventing functions, and tectosilicate of 20 to 25 parts by weight, which has moisture absorbing and contaminant adsorption suppressing functions.

Here, it is disadvantageous in absorption of moisture and resistance to flame if the elvan of 30 parts by weight or less is poured, and it is disadvantageous in prevention of adsorption of contaminants if the elvan of 35 parts by weight or more is poured.

Furthermore, the effect of suppressing adsorption of contaminants deteriorates if tectosilicate of 20 parts by weight or less is poured and the effect of absorbing moisture deteriorates if tectosilicate of 25 parts by weight or more is poured.

Furthermore, the powder is manufactured by further mixing volcanic ash of 100 parts by weight and titanium (TiO₂) of 30 to 35 parts by weight to make the color of the powder after the mixing whiter.

According to another embodiment of the inventive concept, the secondary coating made when the outer surface is water repellency coated is a water repellent agent obtained by coating one or more resins selected from a group consisting of silane-based components and siloxane-based components filmed with minerals after the primary coating film is formed.

Furthermore, the water repellent agent is a mixture obtained by mixing water of 100 parts by weight and a diluted solution of 15 to 20 parts by weight, in which the silane or siloxane acid is diluted.

Furthermore, the diluted solution is manufactured by preparing the silane or siloxane acid in the form of powder as a solid, preparing naphtha or a solvent as the solvent for the solid, and mixing the solvent of 100 parts by weight and the solid of 20 to 40 parts by weight.

In the plurality of embodiments described above, it is preferable that the thicknesses of the primary coating of the water absorption coating and the primary coating of the water repellency coating be 0.2 to 0.5 mm to thermally insulate the interior and the exterior of the panel board. Detailed features and advantages of the inventive concept will become clearer in the following detailed description with reference to the accompanying drawings.

### BRIEF DESCRIPTION OF THE FIGURES

The above and other objects and features will become apparent from the following description with reference to the following figures, wherein like reference numerals refer to like parts throughout the various figures unless otherwise specified, and wherein:

FIG. 1 illustrates a state in which the shape of a panel board of the inventive concept is looked down;

FIG. 2 illustrates a cross-sectional shape of a panel board of the inventive concept;

FIG. 3 illustrates a partially-sectional shape of a wall of a panel board of the inventive concept;

FIG. 4 is a flowchart illustrating a process of manufacturing a coating agent used for primary coating of the inventive concept;

FIGS. 5A and 5B illustrate a coating state of a coating agent used for primary coating of the inventive concept; and

FIG. 6 illustrates a coating state of a coating agent used for secondary coating of the inventive concept.

### DETAILED DESCRIPTION

Hereinafter, a preferred embodiment of the inventive concept will be described with reference to the accompanying drawings. It should be noted that the drawings are not to precise scale and may be exaggerated in thickness of lines or size of components for descriptive convenience and clarity.

In addition, terms used herein are defined by taking functions of the inventive concept into account and can be changed according to user or operator custom or intention. Therefore, definition of the terms should be made according to the overall disclosure set forth herein.

Moreover, the following embodiment is not intended to limit the scope of the inventive concept but is merely an exemplary item of the elements suggested in the claims of the inventive concept, and the embodiment including the elements included in the technical spirit throughout the specification and being replaceable by equivalents may fall within the scope of the inventive concept.

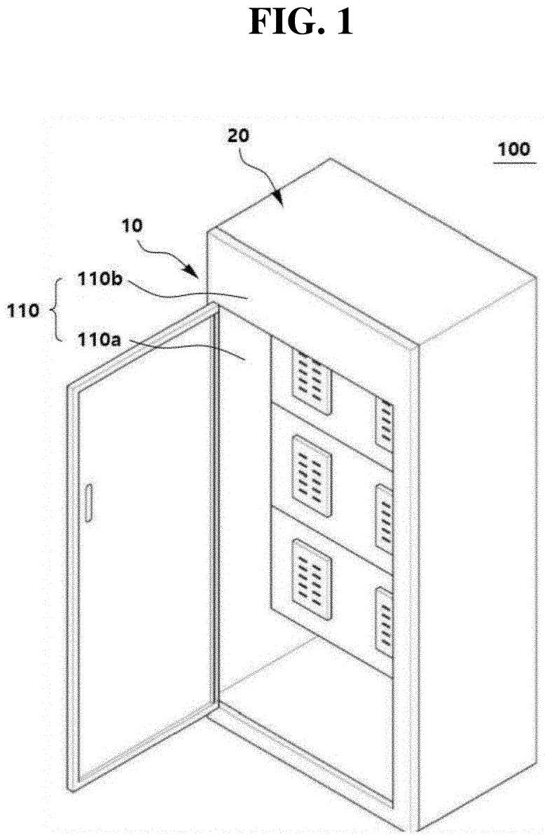

FIG. 1 illustrates a state in which the shape of a panel board 100 of the inventive concept is looked down.

Referring to FIG. 1, the panel board 100 includes an outer wall panel 10 manufactured in a specific standard and a roof panel 20 coupled to an upper side of the outer wall panel 10 to define a roof thereof, and having a space part, in which various pieces of electric power equipment are installed, on the inner side thereof, wherein an interior and an exterior of a wall of the panel board 100 are coated such that moisture absorption capacities of the interior and the exterior of the wall are different, whereby the moisture in the interior of the panel board 100 may be automatically adjusted.

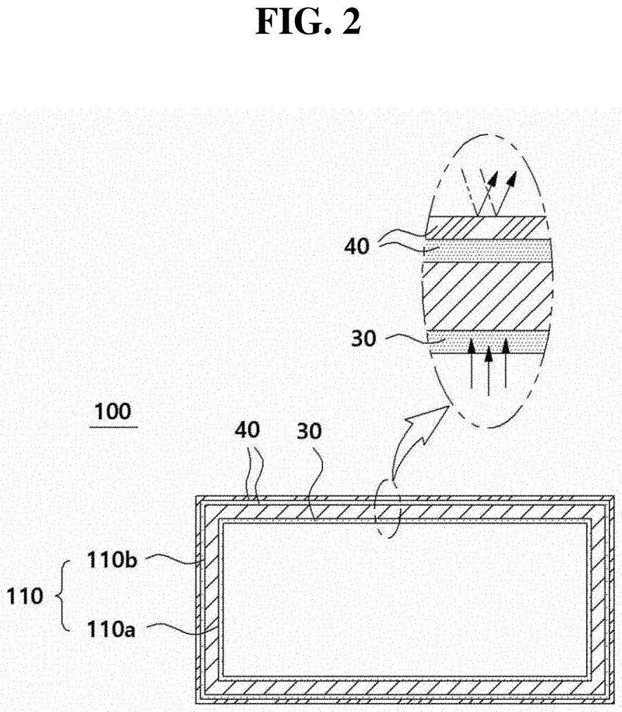

FIG. 2 illustrates a cross-sectional shape of a panel board of the inventive concept.

Referring to FIG. 2, in a detailed description of the coating state of the panel board 100, water absorption coating 30 of absorbing moisture is performed on an inner surface 110a of the wall of the panel board 100, water repellency coating 40 of suppressing absorption of moisture is performed on an outer surface 110b of the wall of the panel board 100, moisture is absorbed to an interior of the panel board 100 due to the water absorption coating of the inner surface 110a, and moisture is prevented from permeating into the interior of the panel board 100 due to the water repellency coating 40 of the outer surface 110b.

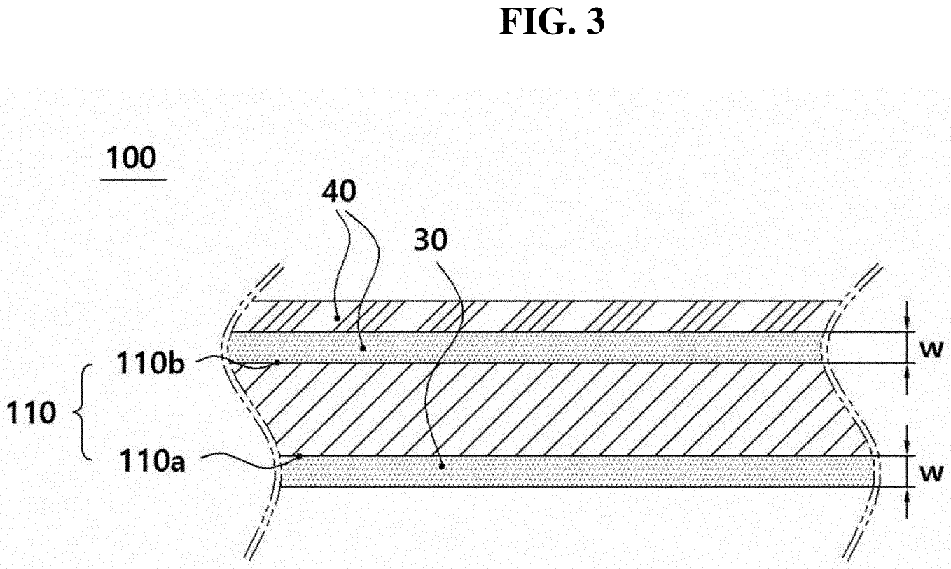

FIG. 3 illustrates a partially-sectional shape of a wall of a panel board of the inventive concept.

Referring to FIG. 3, the wall 110 of the panel board 100 is a single panel member, and the water absorption coating 30 of the inner surface 110a is finished through primary coating, and the water repellency coating 40 of the outer surface 110b is finished by performing secondary coating on an upper surface, on which the primary coating has been performed, after the primary coating.

According to the embodiment of the inventive concept, the primary coating of the water absorption coating 30 and the primary coating of the water repellency coating 40 are performed such that a plurality of pores are generated after the coating, and the plurality of pores are generated due to porous composites.

Furthermore, according to another embodiment of the inventive concept, the primary coating of the water absorption coating 30 and the primary coating of the water repellency coating 40 are performed such that a plurality of pores are generated after the coating, and the plurality of pores are generated due to bubbles generated during spray coating.

According to the embodiment, the thicknesses w of the primary coating of the water absorption coating 30 and the primary coating of the water repellency coating 40 may be 0.2 mm to 0.5 mm to thermally block the interior and the exterior of the panel board 100, thereby preventing a dew condensation by reducing a difference between the temperatures of the exterior and the interior of the panel board.

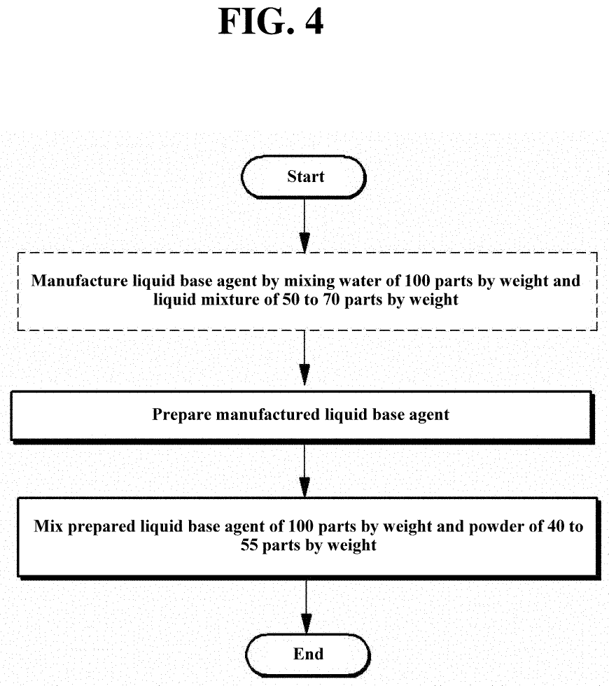

FIG. 4 is a flowchart illustrating a process of manufacturing a coating agent used for primary coating of the inventive concept.

Referring to FIG. 4, a coating agent for the primary coating of the water absorption coating 30 and the primary coating of the water repellency coating 40 is manufactured by mixing a liquid base agent of 100 parts by weight and powder of 40 to 55 parts by weight, and the liquid base agent is obtained by mixing water of 100 parts by weight and a liquid mixture of 50 to 70 parts by weight.

The liquid mixture is manufactured by mixing a polyurethane dispersion (PUD) resin of 100 parts by weight and an acryl resin of 40 to 55 parts by weight. Because the PUD resin is viscos, the coating agent is bonded to the wall of the panel board without any separate adhesive when the coating agent is manufactured by using the PUD resin.

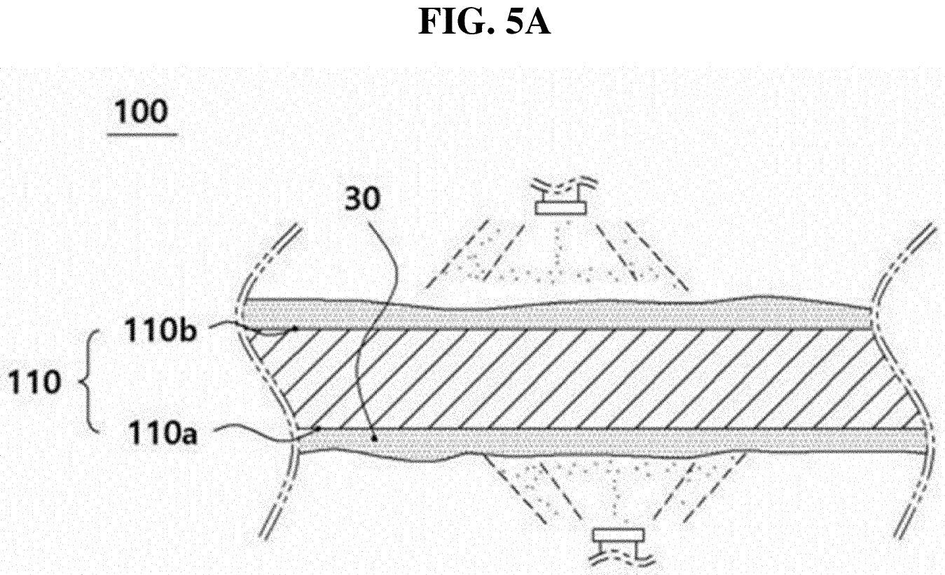

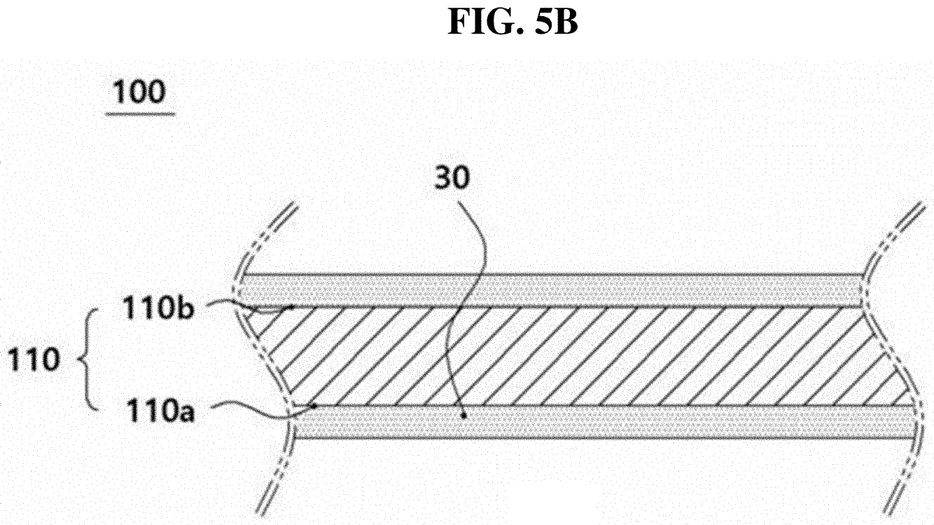

FIGS. 5A and 5B illustrate a coating state of a coating agent used for primary coating of the inventive concept.

Referring to FIG. 5A, porosity characteristics may be given to the primary coating according to the correct embodiment of the inventive concept by uniformly ejecting the coating agent used for the primary coating manufactured as described with reference to FIG. 4 to the wall 110 in a spray scheme. Then, it is preferable that the thickness of the ejected coating agent be constant. Furthermore, the method for ejecting the coating agent in the spray scheme is a technology that is generally known to a person who intends to carry out the inventive concept, and a detailed description thereof will be omitted. The coating agent is coated on the inner surface 110a and the outer surface 110b of the wall, and the primary coating coated on the inner surface 110a of the wall defines the water absorption coating 30.

Furthermore, referring to FIG. 5B, in a description of another embodiment of the inventive concept, the mixed powder in FIG. 4 may be manufactured by mixing volcanic ash of 100 parts by weight, which is excellent in absorption of moisture and insulation of heat due to the porous structure thereof, and diatomite of 70 to 75 parts by weight, which is excellent in absorption of moisture, prevention of adsorption of contaminants, and performance of insulation of heat due to the porous structure thereof and dolomite of 55 to 65 parts by weight, which is excellent in a filling effect and performance of prevention of adsorption of contaminants. Then, the coating agent used for the primary coating has porosity characteristics by itself due to the characteristics of a composite without requiring spray coating to form the porous structure separately, due to the powder having the porous structure.

Here, the porosity of the diatomite is advantageous in absorption of moisture and is effective in adsorption of contaminants and insulation of heat. Accordingly, it is disadvantageous because the amount of absorbed moisture is small if the diatomite of 70 parts by weight or less is poured, and it is disadvantageous in prevention of adsorption of contaminants if the diatomite of 75 parts by weight or more is poured.

Furthermore, the dolomite is advantageous in a filling effect due to the low price, and it is disadvantageous in prevention of adsorption of contaminants if the dolomite of 55 parts by weight or less is poured and it is disadvantageous in absorption of moisture if the dolomite of 65 parts by weight or more is poured.

Furthermore, according to the embodiment, the powder may be manufactured by further mixing volcanic ash of 100 parts by weight and elvan of 30 to 35 parts by weight, which has moisture absorbing, fire retarding, and contaminant adsorption preventing functions, and tectosilicate of 20 to 25 parts by weight, which has moisture absorbing and contaminant adsorption suppressing functions. Furthermore, the powder may be manufactured by further mixing volcanic ash of 100 parts by weight and titanium dioxide (TiO₂) of 30 to 35 parts by weight to make the color of the powder after the mixing whiter.

Here, the color of the powder becomes grayer and then murkier if the titanium dioxide (TiO₂) of 30 parts by weight or less is poured, and the moisture absorption rate decreases if the titanium dioxide (TiO₂) of 35 parts by weight or more is poured.

Accordingly, if the titanium dioxide (TiO₂) of 30 to 35 parts by weight is mixed, the color becomes whiter and becomes better in absorption of moisture.

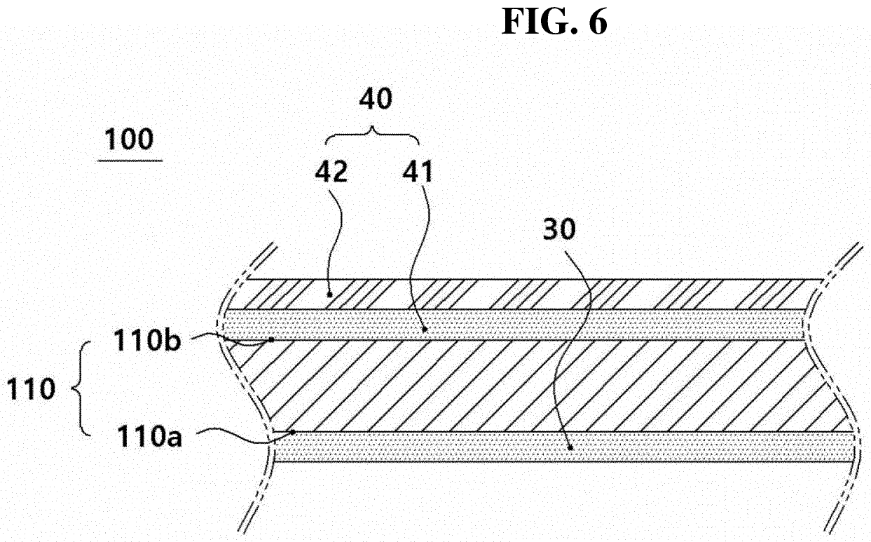

FIG. 6 illustrates a coating state of a coating agent used for secondary coating of the inventive concept.

Referring to FIG. 6, a secondary coating 42 performed during the water repellency coating 40 of the outer surface 110b is coated on the entire outer surface 110b to cover a primary coating 41 coated on the outer surface 110b after the primary coating. Then, the method for coating the coating agent used for the secondary coating may use various technologies generally widely known to a person who intends to carry out the inventive concept, and a detailed description thereof will be omitted.

Furthermore, the secondary coating is a water repellent agent obtained by coating one or more resins selected from a group consisting of silane-based components and siloxane-based components filmed with minerals after the primary coating film is formed. The water repellent agent is a mixture obtained by mixing water of 100 parts by weight and a diluted solution of 15 to 20 parts by weight, in which the silane or siloxane acid is diluted. The diluted solution is manufactured by preparing the silane or siloxane acid in the form of powder as a solid, preparing naphtha or a solvent as the solvent for the solid, and mixing the solvent of 100 parts by weight and the solid of 20 to 40 parts by weight.

According to the inventive concept, moisture in the interior of the panel board may be adjusted in an eco-friendly manner by making the coating on the outer surface and the inner surface of the wall of the panel board different, and the performance of the panel board may be improved by reducing the difference between the temperatures of the outside and the inside of the panel board to prevent a dew condensation phenomenon of the conventional panel board.

Until now, although the inventive concept has been described in detail through the detailed embodiment, the embodiment is for describing the inventive concept in detail, and the inventive concept is not limited thereto but may be modified or improved by an ordinary person in the art, to which the inventive concept pertains, without departing from the technical spirit of the inventive concept.

Both of a simple modification and change of the inventive concept pertains to the category of the inventive concept, and a detailed protection scope of the inventive concept will become clearer by the claims attached.

What is claimed is:

1. A panel board comprising an outer wall panel manufactured in a specific standard and a roof panel coupled to an upper side of the outer wall panel to define a roof thereof, and having a space part, in which various pieces of electric power equipment are installed, on the inner side thereof, wherein an interior and an exterior of a wall of the panel board are coated such that moisture absorption capacities of the interior and the exterior of the wall are different,
wherein water absorption coating of absorbing moisture is performed on an inner surface of the wall of the panel board, water repellency coating of suppressing absorption of moisture is performed on an outer surface of the wall of the panel board, moisture is absorbed to an interior of the panel board due to the water absorption coating of the inner surface, and moisture is prevented from permeating into the interior of the panel board due to the water repellency coating of the outer surface, and
wherein the wall of the panel board is a single panel member, and the water absorption coating of the inner surface is finished through primary coating, and the water repellency coating of the outer surface is finished by performing secondary coating on an upper surface, on which the primary coating has been performed, after the primary coating.

2. The panel board of claim 1, wherein the primary coating of the water absorption coating and the primary coating of the water repellency coating are performed such that a plurality of pores are generated after the coating, and the plurality of pores are generated due to porous composites.

3. The panel board of claim 1, wherein the primary coating of the water absorption coating and the primary coating of the water repellency coating are performed such that a plurality of pores are generated after the coating, and the plurality of pores are generated due to bubbles generated during spray coating.

4. The panel board of claim 1, wherein a coating agent for the primary coating of the water absorption coating and the primary coating of the water repellency coating is manufactured by mixing a liquid base agent of 100 parts by weight and powder of 40 to 55 parts by weight.

5. The panel board of claim 4, wherein the liquid base agent is obtained by mixing water of 100 parts by weight and a liquid mixture of 50 to 70 parts by weight.
